(19) United States
(12) Patent Application Publication
(10) Pub. No.: US 2024/0395585 A1
(43) Pub. Date: Nov. 28, 2024

(54) SUBSTRATE PROCESSING APPARATUS AND SUBSTRATE TRANSFER METHOD

(71) Applicant: Tokyo Electron Limited, Tokyo (JP)

(72) Inventor: Manabu HONMA, Oshu City (JP)

(21) Appl. No.: 18/663,611

(22) Filed: May 14, 2024

(30) Foreign Application Priority Data
May 23, 2023 (JP) 2023-084558

(51) Int. Cl. H01L 21/673; H01L 21/67; H01L 21/677

(52) U.S. Cl. CPC H01L 21/67309; H01L 21/67259; H01L 21/67778

(57) ABSTRACT

A substrate processing apparatus includes: a boat configured to hold substrates by arranging the substrates in a horizontal posture and in multiple stages along a vertical direction; a plate-shaped member provided along an outer periphery of each substrate of the substrates held by the boat; and a driver configured to change a relative position between the boat and the plate-shaped member in the vertical direction.

### CROSS-REFERENCE TO RELATED APPLICATION

This application is based upon and claims the benefit of priority from Japanese Patent Application No. 2023-084558, filed on May 23, 2023, the entire contents of which are incorporated herein by reference.

### TECHNICAL FIELD

The present disclosure relates to a substrate processing apparatus and a substrate transfer method.

### BACKGROUND

A vertical type substrate processing apparatus that processes a plurality of substrates by supplying a processing gas into a processing container, while a substrate holder holding the plurality of substrates is accommodated in the processing container, is known (e.g., see Patent Document 1). As the substrate holder, a so-called ring boat may be used, in which a plurality of support columns are provided between a top plate and a bottom plate arranged vertically opposite to each other, a ring member having a flat support surface is provided on the plurality of support columns, and the substrates are supported by the support surface of the ring member.

### PRIOR ART DOCUMENT

### Patent Document

Patent Document 1: Japanese Patent No. 3122364

### SUMMARY

According to one embodiment of the present disclosure, a substrate processing apparatus includes: a boat configured to hold substrates by arranging the substrates in a horizontal posture and in multiple stages along a vertical direction; a plate-shaped member provided along an outer periphery of each substrate of the substrates held by the boat; and a driver configured to change a relative position between the boat and the plate-shaped member in the vertical direction.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view showing a substrate processing apparatus according to a first embodiment.

FIG. 2 is a cross-sectional view taken along line II-II in FIG. 1.

FIG. 3 is a cross-sectional view 1 illustrating a substrate transfer method according to the first embodiment.

FIG. 4 is a cross-sectional view 2 illustrating the substrate transfer method according to the first embodiment.

FIG. 5 is a cross-sectional view 3 illustrating the substrate transfer method according to the first embodiment.

FIG. 6 is a cross-sectional view 4 illustrating the substrate transfer method according to the first embodiment.

FIG. 7 is a cross-sectional view 5 illustrating the substrate transfer method according to the first embodiment.

FIG. 8 is a cross-sectional view showing a substrate processing apparatus according to a second embodiment.

FIG. 9 is a cross-sectional view 1 illustrating a substrate transfer method according to the second embodiment.

FIG. 10 is a cross-sectional view 2 illustrating the substrate transfer method according to the second embodiment.

FIG. 11 is a cross-sectional view 3 illustrating the substrate transfer method according to the second embodiment.

FIG. 12 is a cross-sectional view 4 illustrating the substrate transfer method according to the second embodiment.

FIG. 13 is a cross-sectional view 5 illustrating the substrate transfer method according to the second embodiment.

FIG. 14 is a cross-sectional view showing a substrate processing apparatus according to a third embodiment.

FIG. 15 is a cross-sectional view 1 illustrating a substrate transfer method according to a third embodiment.

FIG. 16 is a cross-sectional view 2 illustrating the substrate transfer method according to the third embodiment.

FIG. 17 is a cross-sectional view 3 illustrating the substrate transfer method according to the third embodiment.

FIG. 18 is a cross-sectional view 4 illustrating the substrate transfer method according to the third embodiment.

FIG. 19 is a cross-sectional view 5 illustrating the substrate transfer method according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the attached drawings, the same or corresponding reference numerals are used to identify the same or corresponding members or elements, and thus a duplicative description thereof will be omitted.

### First Embodiment

### (Substrate Processing Apparatus)

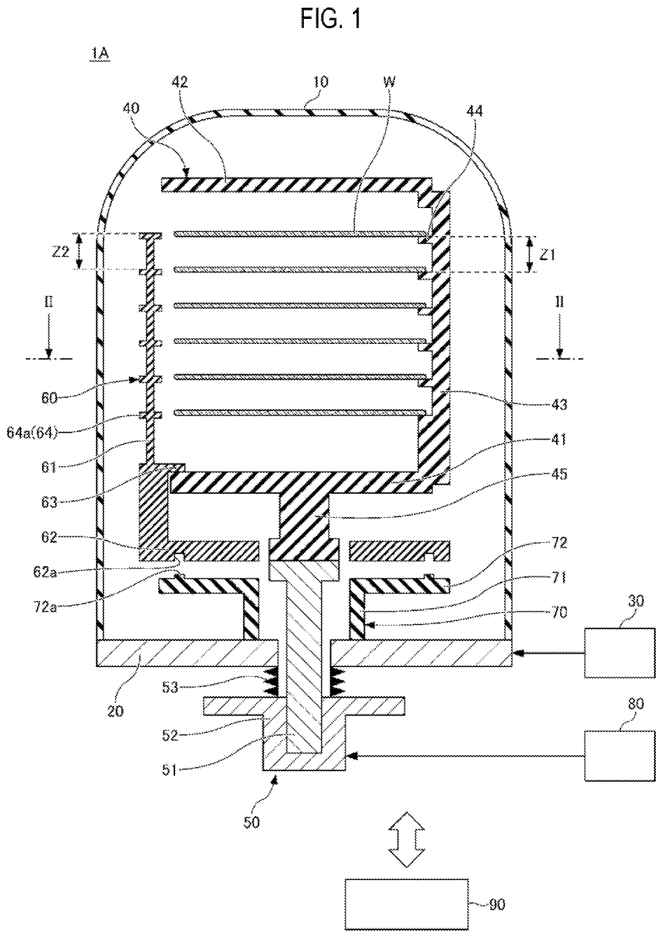

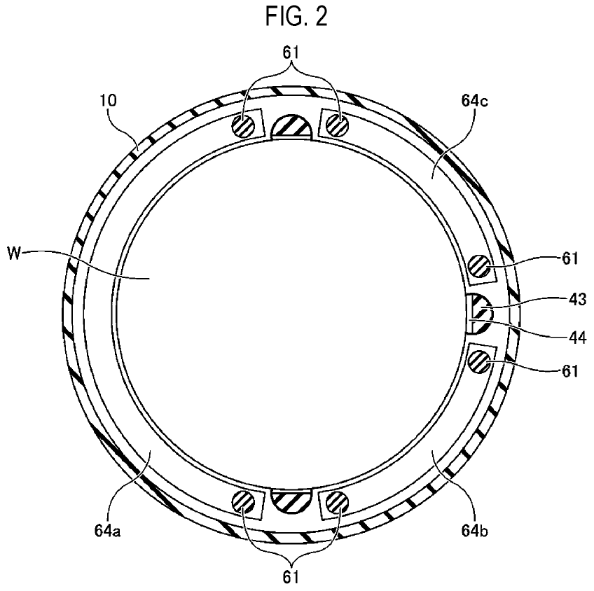

A substrate processing apparatus 1A according to a first embodiment will now be described with reference to FIGS. 1 and 2. FIG. 1 is a cross-sectional view showing the substrate processing apparatus 1A according to the first embodiment. FIG. 2 is a cross-sectional view taken along line II-II in FIG. 1.

The substrate processing apparatus 1A includes a reaction tube 10, a lid 20, a lid driver 30, a boat 40, a boat support 50, a ring 60, a ring stage 70, a boat driver 80, and a controller 90.

The reaction tube 10 has a cylindrical shape with a ceiling and an open lower end. The reaction tube 10 is made of quartz, for example. A gas supply (not shown) is connected to the reaction tube 10. The gas supply supplies various gases to an inside of the reaction tube 10. The gas supply may include a gas source, a gas supply pipe, a valve, a mass flow controller, and the like. A gas discharger (not shown) is connected to the reaction tube 10. The gas discharger discharges gases inside the reaction tube 10. The gas discharger may include a gas discharge pipe, a pressure adjustment valve, a vacuum pump, and the like.

The lid 20 closes an opening of the lower end of the reaction tube 10. As a result, the inside of the reaction tube 10 is sealed. The lid 20 is made of a metal such as stainless steel and the like.

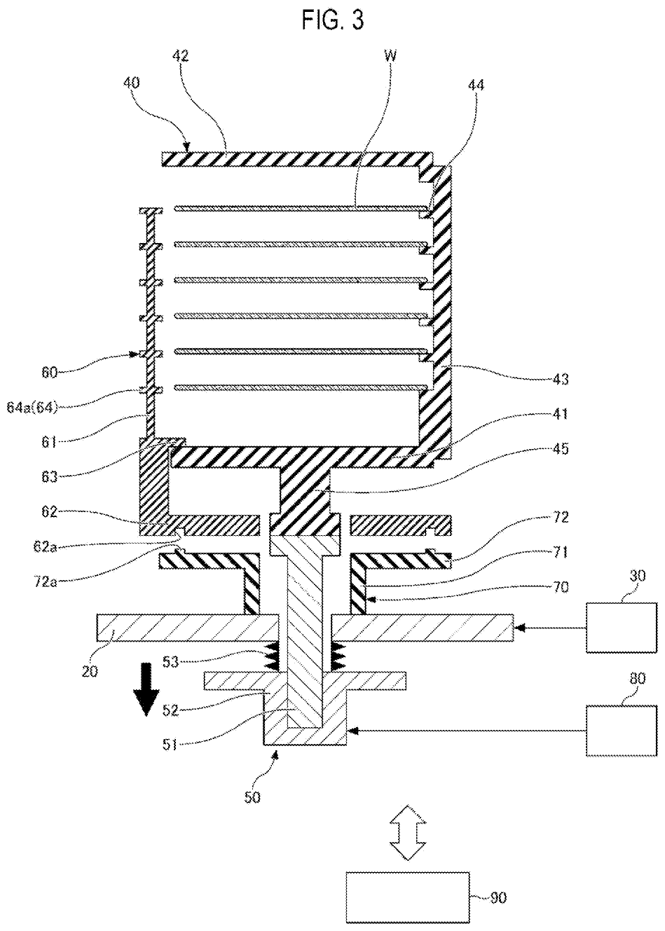

The lid driver 30 raises and lowers the lid 20 between a raised position (a position shown in FIG. 1) and a lowered position (a position shown in FIG. 3). The raised position is a position at which the lid 20 closes the opening of the lower end of the reaction tube 10. The lowered position is a position at which the lid 20 opens the opening of the lower end of the reaction tube 10. The lid driver 30 is a linear motion mechanism including, for example, a ball screw and a servo-motor.

The boat 40 is inserted into or removed from the reaction tube 10. The boat 40 holds substrates W by arranging the substrates W in a horizontal posture and in multiple stages along a vertical direction. The substrate W is, for example, a semiconductor wafer. The boat 40 is configured to hold a plurality of (e.g., 25 to 200) substrates W. The boat 40 is made of quartz, for example. The boat 40 includes a bottom plate 41, a top plate 42, a support column 43, a holding claw 44, and a leg 45.

The bottom plate 41 has a disc shape with an outer diameter larger than an outer diameter of the substrate W.

The top plate 42 is provided above the bottom plate 41 and spaced apart from the bottom plate 41. The top plate 42 faces the bottom plate 41. Like the bottom plate 41, the top plate 42 has a disk shape with an outer diameter larger than the outer diameter of the substrate W.

The support column 43 has a rod shape extending in a vertical direction. A plurality of (for example, three) support columns 43 are provided along a circumferential direction of the bottom plate 41. Each support column 43 connects the bottom plate 41 and the top plate 42.

A plurality of holding claws 44 are provided along a vertical direction of each support column 43. Positions along the vertical direction at which the plurality of holding claws 44 are provided are the same among the plurality of support columns 43. The substrates W are held in the horizontal posture by the holding claws 44 provided at the same heights among the support columns 43.

The leg 45 extends downward from a center of a lower surface of the bottom plate 41. The leg 45 is connected to an upper end of a rotating shaft 51.

The boat support 50 includes the rotating shaft 51, a bearing 52, and a bellows 53. The rotating shaft 51 is connected to a lower end of the leg 45. The rotating shaft 51 extends below the lid 20 by passing through the lid 20. The bearing 52 is installed at a lower portion of the rotating shaft 51. The bearing 52 rotatably supports the rotating shaft 51 around a vertical axis. The bellows 53 is provided between the lid 20 and the bearing 52 so as to surround an outer periphery of the rotating shaft 51. Thereby, the reaction tube 10 is kept airtight.

The ring 60 is made of quartz, for example. The ring 60 includes a support column 61, a bottom plate 62, an intermediate plate 63, and a ring body 64.

The support column 61 has a rod shape extending in a vertical direction. A plurality of (for example, six) support columns 61 are provided around the substrates W along a circumferential direction of the substrate W.

The bottom plate 62 is connected to a lower end of the support column 61. The bottom plate 62 has a disc shape with an opening in a center thereof. The leg 45 is inserted through the opening of the bottom plate 62. The bottom plate 62 is configured to be mountable on the ring stage 70. A lower surface of the bottom plate 62 is provided with, for example, a concave portion 62a.

The intermediate plate 63 is connected to the support column 61 above the bottom plate 62. The intermediate plate 63 is configured to be mountable on the bottom plate 41. The intermediate plate 63 has an annular plate shape with an inner diameter smaller than an outer diameter of the bottom plate 41. An inner peripheral edge of the intermediate plate 63 is configured to be mountable on an outer peripheral edge of the bottom plate 41.

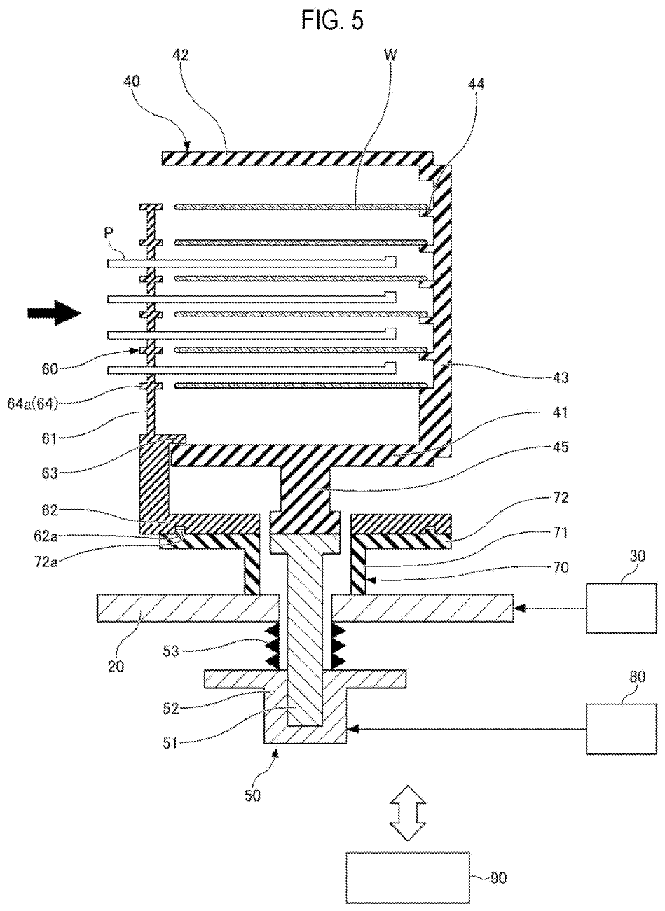

The ring body 64 is connected to the support column 61 above the intermediate plate 63. A plurality of ring bodies 64 are provided along a vertical direction. A pitch Z2 of the plurality of ring bodies 64 is the same as a pitch Z1 of the plurality of holding claws 44. Each ring body 64 is a plate-shaped member provided along an outer periphery of each substrate W held by the boat 40. Each ring body 64 includes three arc-shaped split rings 64a, 64b, and 64c in a circumferential direction of the reaction tube 10. Each of the split rings 64a, 64b, and 64c is supported by, for example, two support columns 61. The split ring 64a is provided to include a position overlapping with a movement path of picks P (FIG. 5) of a transfer device (not shown), when viewed in a plan view, when the picks P take out the substrates W held by the boat 40. Each of the split rings 64b and 64c is located on a back side when viewed from an insertion direction of the picks P and is provided between two adjacent support columns 43 in the circumferential direction of the reaction tube 10. Each of the split rings 64b and 64c is provided at a position that does not overlap with the movement path of the picks P of the transfer device when viewed in a plan view. Although not shown, the support column 61 supporting each of the split rings 64b and 64c is provided such that, for example, a lower portion thereof is attachable to or removable from the bottom plate 41. Although not shown, the support column 61 supporting each of the split rings 64b and 64c may be provided such that an upper portion thereof is attachable to or removable from the top plate 42. Although now shown, the support column 61 supporting each of the split rings 64b and 64c may have the lower portion attachable to or removable from the bottom plate 41 and the upper portion attachable to or removable from the top plate 42. In this way, each of the split rings 64b and 64c is provided at a position that does not overlap with the movement path of the picks P of the transfer device when viewed in a plan view, so it is not necessary for each of the split rings 64b and 64c to be raised or lowered relative to the boat 40 and each of the split rings 64b and 64c may be provided to be attachable to or removable from a part of the boat 40. However, each of the split rings 64b and 64c may be raised or lowered relative to the boat 40. While the example in FIG. 2 shows that each of the split rings 64b and 64c is supported by the support column 61, each of the split rings 64b and 64c may have a structure in which each of the split rings 64b and 64c is not supported by the support column 61 and is fixed to the support column 43 by welding or the like. In this case, the ring 60 may not have the support column 61 supporting the split rings 64b and 64c.

The ring stage 70 is made of quartz, for example. The ring stage 70 includes a cylindrical portion 71 and a flange portion 72. The cylindrical portion 71 is fixed on the lid 20. The cylindrical portion 71 surrounds the rotating shaft 51. The flange portion 72 is provided at an upper portion of the cylindrical portion 71 so as to protrude outward in a radial direction of the cylindrical portion 71. The bottom plate 62 is placed on the flange portion 72. Thereby, the ring 60 is held by the ring stage 70. An upper surface of the flange portion 72 is provided with, for example, a convex portion 72a that fits into the concave portion 62a of the bottom plate 62. When the bottom plate 62 is placed on the flange portion 72, the convex portion 72a fits into the concave portion 62a, so that a position of the ring 60 is determined in a horizontal direction with respect to the ring stage 70. It may also be possible that a concave portion is provided on the upper surface of the flange portion 72, and a convex portion that fits into the concave portion is provided on the lower surface of the bottom plate 62.

The boat driver 80 changes a relative position between the boat 40 and the ring 60 in a vertical direction by raising and lowering the boat 40. The boat driver 80 raises and lowers the bearing 52. Thereby, the boat 40 and the rotating shaft 51 are raised and lowered together with the bearing 52. The boat driver 80 is a linear motion mechanism including, for example, a ball screw and a servo-motor.

The controller 90 controls an operation of each portion of the substrate processing apparatus 1A. The controller 90 is, for example, a computer. A computer program for executing the operation of each portion of the substrate processing apparatus 1A is stored in a storage medium. The storage medium may be, for example, a flexible disk, a compact disc, a hard disk, a flash memory, a DVD, etc.

### (Substrate Transfer Method)

An example of a substrate transfer method according to the first embodiment will now be described with reference to FIGS. 3 to 7. Hereinafter, a method of unloading the substrates W held by the boat 40 will be described. The substrates W may be loaded into the boat 40 by a reverse procedure of the unloading method.

FIGS. 3 to 7 are cross-sectional views illustrating the substrate transfer method according to the first embodiment. The substrate transfer method described below is executed by the controller 90 controlling the operation of each portion of the substrate processing apparatus 1A. The substrate transfer method described below is executed, for example, after processing is performed on a plurality of substrates W held by the boat 40 inside the reaction tube 10.

First, as shown in FIG. 3, the lid driver 30 lowers the lid 20 to unload the boat 40 and the ring 60 from the inside of the reaction tube 10. In this case, the intermediate plate 63 is placed on the bottom plate 41, and a height of an upper surface of each ring body 64 is approximately the same as a height of an upper surface of each corresponding substrate W.

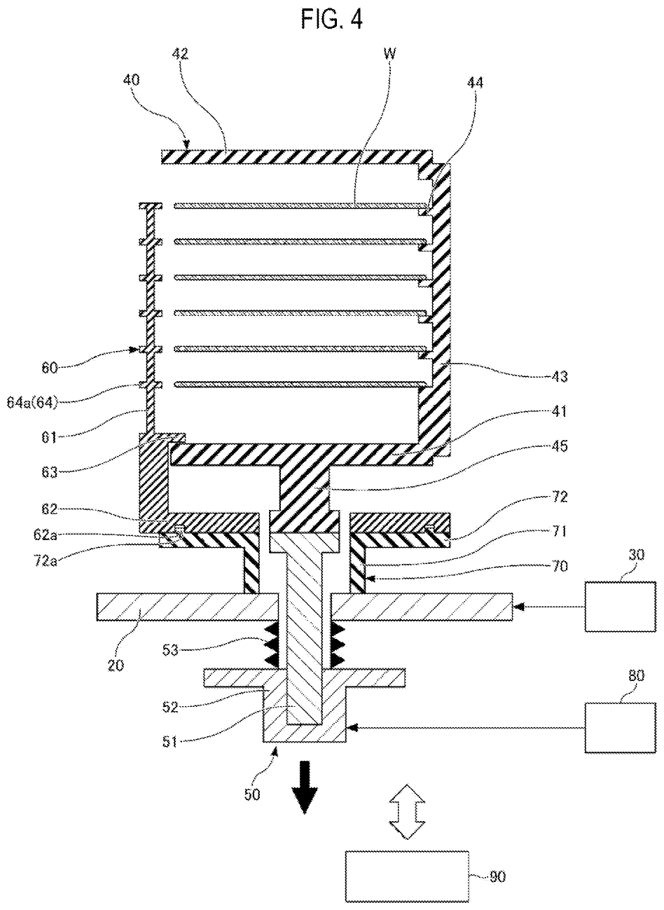

Next, as shown in FIG. 4, the boat driver 80 lowers the boat 40 to place the bottom plate 62 on the flange portion 72. In this case, the convex portion 72a fits into the concave portion 62a, so that the position of the ring 60 is determined in a horizontal direction with respect to the ring stage 70. After the bottom plate 62 is placed on the flange portion 72, the boat driver 80 may further lower the boat 40 to slightly separate (e.g., 0.5 mm to 1.0 mm) a lower surface of the intermediate plate 63 from an upper surface of the bottom plate 41. In this case, since the ring 60 is supported only by the flange portion 72, stability of support of the ring 60 is increased compared to the case in which the ring 60 is supported at two locations, i.e., the bottom plate 41 and the flange portion 72.

Next, as shown in FIG. 5, a transfer device, which is not shown, horizontally moves the picks P so that each pick P is inserted between the substrates W which are vertically adjacent to each other. In this case, since the height of the upper surface of each ring body 64 is approximately the same as the height of the upper surface of each corresponding substrate W, each ring body 64 does not interfere with insertion of the picks P.

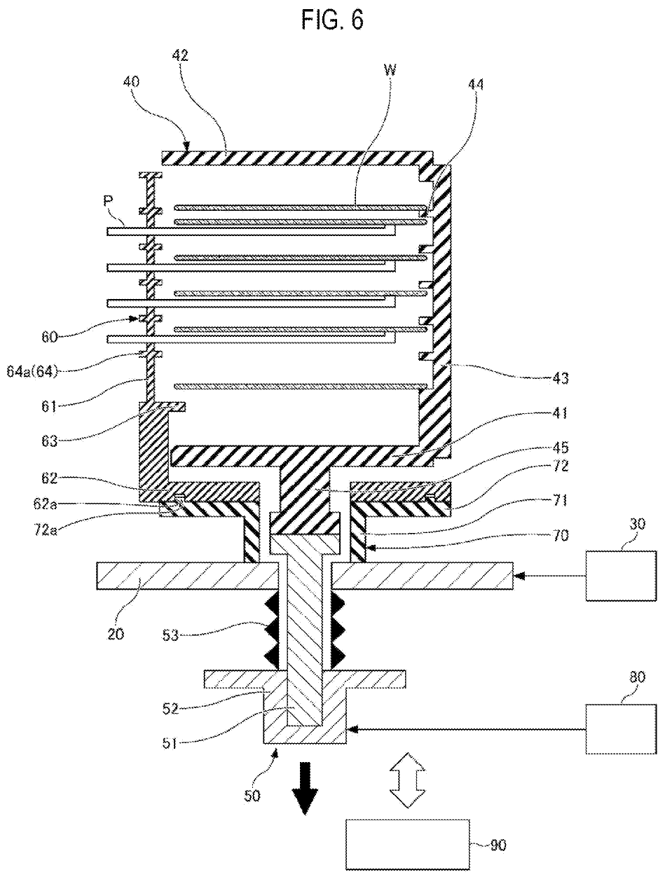

Next, as shown in FIG. 6, the boat driver 80 lowers the boat 40 by the pitch Z1. As a result, the substrates W held by the boat 40 are transferred to the picks P.

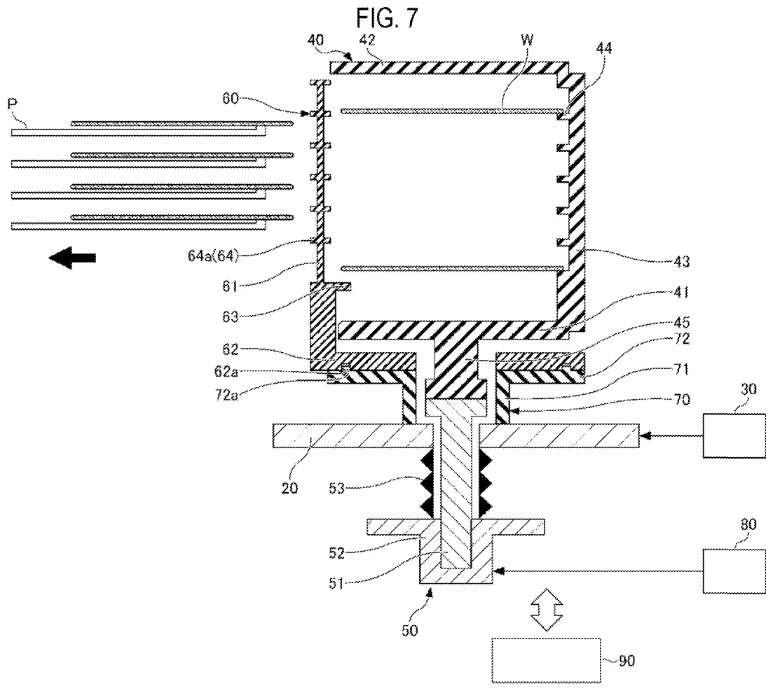

Next, as shown in FIG. 7, the transfer device horizontally moves the picks P holding the substrates W, thereby unloading the picks P from an inside of the boat 40. In this case, since the height of the upper surface of each ring body 64 is approximately the same as the height of the upper surface of each corresponding substrate W, each ring body 64 does not interfere with unloading of the picks P.

Through the above operations, four substrates W are unloaded from the boat 40. By repeating the operations shown in FIGS. 4 to 7, the other substrates W held by the boat 40 may be unloaded. The number of substrates W unloaded from the boat 40 at one time is not limited to four.

According to the first embodiment described above, it is possible to change the relative position between the boat 40 and the ring 60 in a vertical direction. In this case, when the substrates W held by the boat 40 are unloaded by the picks P, the substrates W are transferred from the boat 40 to the picks P by inserting each pick P between the vertically adjacent substrates W and then lowering the boat 40 with respect to the pick P and the ring 60. Therefore, the substrates W may be held by the boat 40 at the same pitch as in the case without the ring 60. That is, the substrates W may be held at a narrow pitch.

### Second Embodiment

### (Substrate Processing Apparatus)

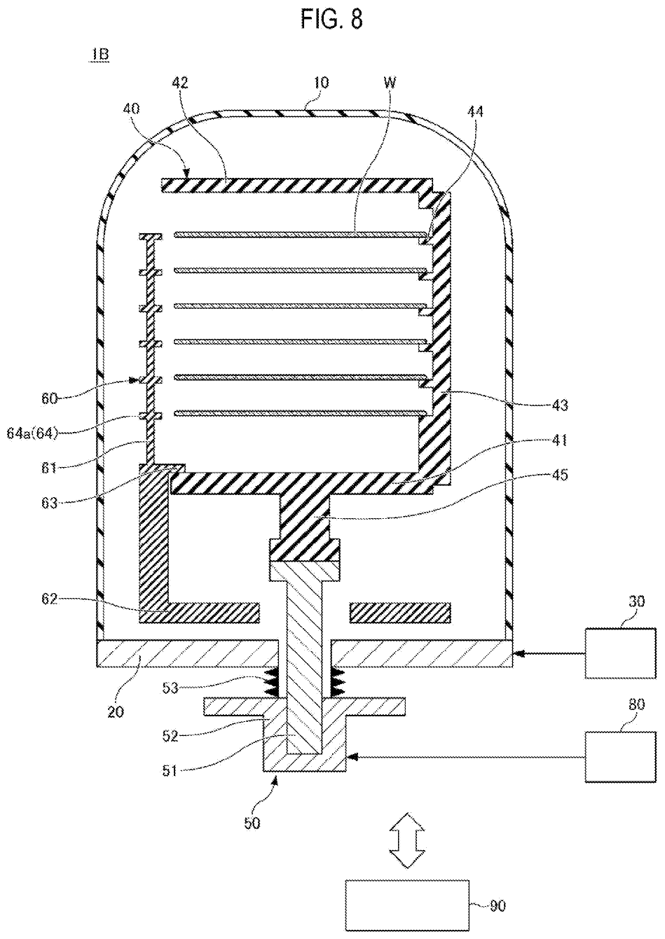

A substrate processing apparatus 1B according to a second embodiment will now be described with reference to FIG. 8. FIG. 8 is a cross-sectional view showing the substrate processing apparatus 1B according to the second embodiment.

The substrate processing apparatus 1B differs from the substrate processing apparatus 1A in that the substrate processing apparatus 1B does not include the ring stage 70 and the bottom plate 62 is placed on the lid 20. The other configurations of the substrate processing apparatus 1B may be the same as the configurations of the substrate processing apparatus 1A. Hereinafter, a description will be given focusing on the configurations different from the substrate processing apparatus 1A.

The bottom plate 62 is configured to be mountable on the lid 20. A concave portion (not shown) may be provided on the lower surface of the bottom plate 62, and a convex portion (not shown) that fits into the concave portion may be provided on an upper surface of the lid 20. In this case, when the bottom plate 62 is placed on the lid 20, a position of the ring 60 is determined in a horizontal direction with respect to the lid 20 by fitting the convex portion into the concave portion.

### (Substrate Transfer Method)

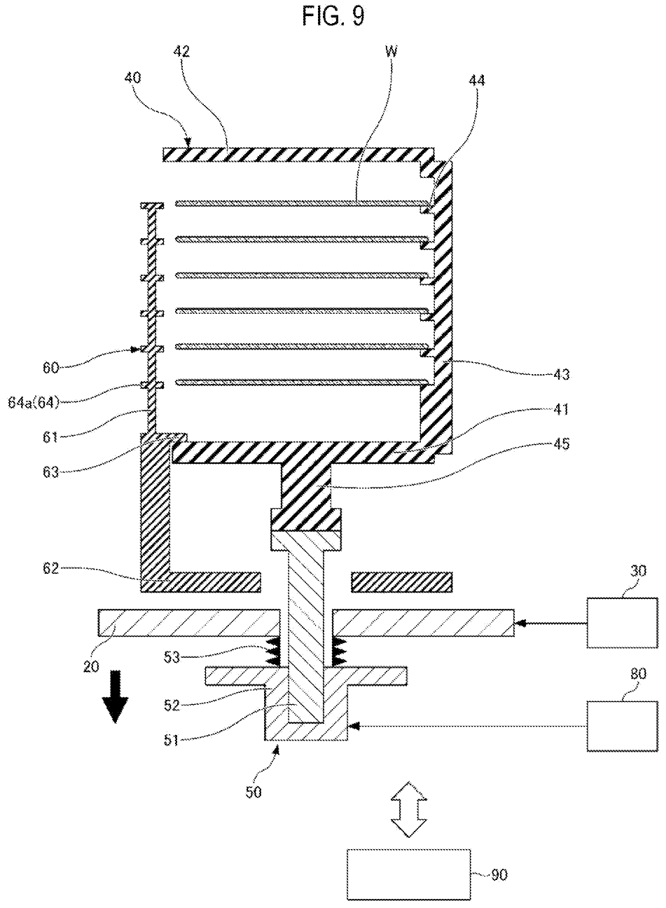

An example of the substrate transfer method according to the second embodiment will now be described with reference to FIGS. 9 to 13. Hereinafter, a method of unloading the substrates W held by the boat 40 will be described. The substrates W may be loaded into the boat 40 by a reverse procedure of the unloading method.

FIGS. 9 to 13 are cross-sectional views illustrating the substrate transfer method according to the second embodiment. The substrate transfer method described below is executed by the controller 90 controlling the operation of each portion of the substrate processing apparatus 1B. The substrate transfer method described below is executed, for example, after processing is performed on a plurality of substrates W held by the boat 40 inside the reaction tube 10.

First, as shown in FIG. 9, the lid driver 30 lowers the lid 20 to unload the boat 40 and the ring 60 from the inside of the reaction tube 10. In this case, the intermediate plate 63 is placed on the bottom plate 41, and the height of an upper surface of each ring body 64 is approximately the same as the height of an upper surface of each corresponding substrate W.

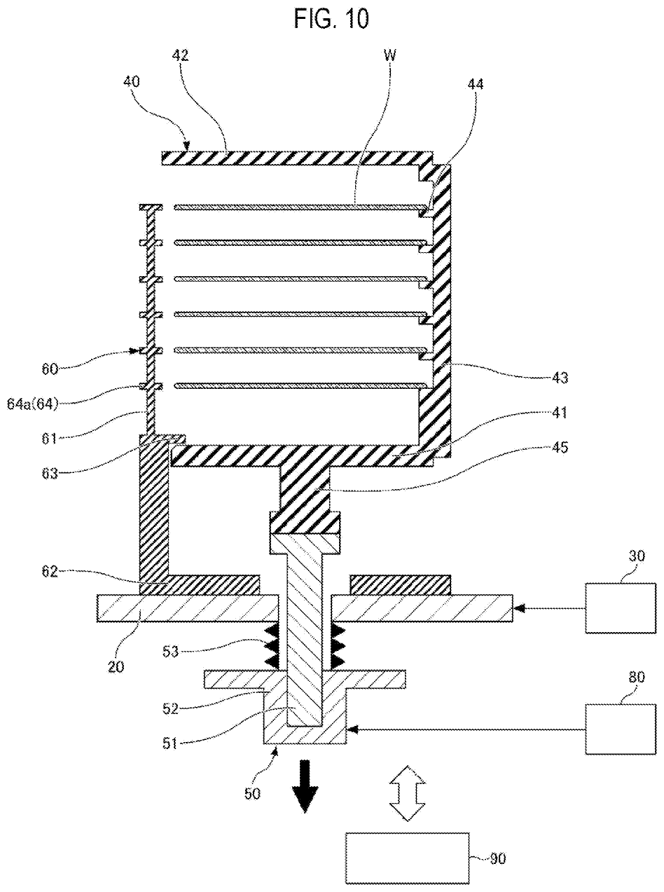

Next, as shown in FIG. 10, the boat driver 80 lowers the boat 40 to place the bottom plate 62 on the lid 20. After the bottom plate 62 is placed on the lid 20, the boat driver 80 may further lower the boat 40 to slightly separate (e.g., 0.5 mm to 1.0 mm) the lower surface of the intermediate plate 63 from the upper surface of the bottom plate 41. In this case, since the ring 60 is supported only by the lid 20, stability of support of the ring 60 is increased compared to the case in which the ring 60 is supported at two locations, i.e., the bottom plate 41 and the lid 20.

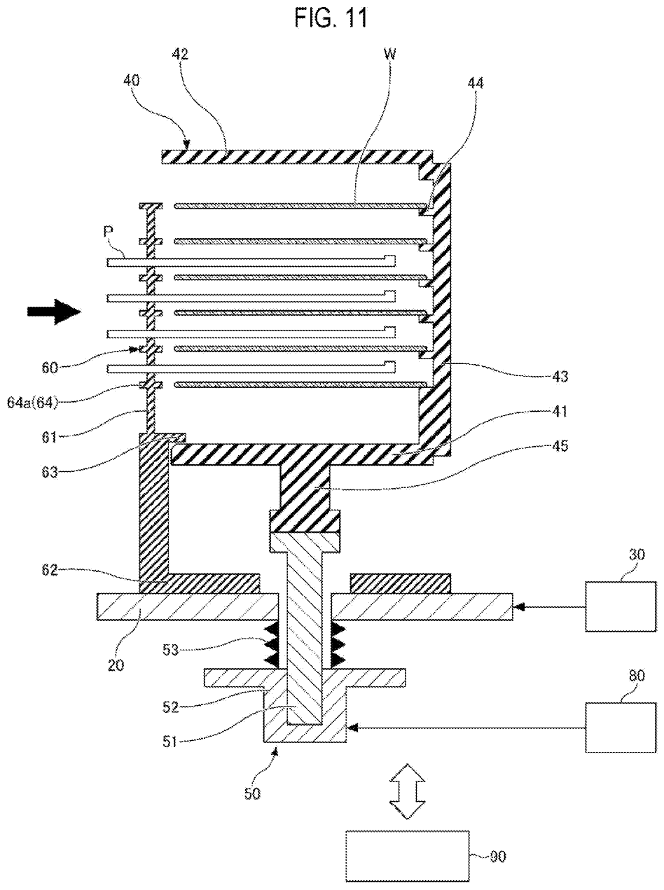

Next, as shown in FIG. 11, a transfer device, which is not shown, horizontally moves the picks P to insert each pick P between the vertically adjacent substrates W. In this case, since the height of the upper surface of each ring body 64 is approximately the same as the height of the upper surface of each corresponding substrate W, each ring body 64 does not interfere with insertion of the picks P.

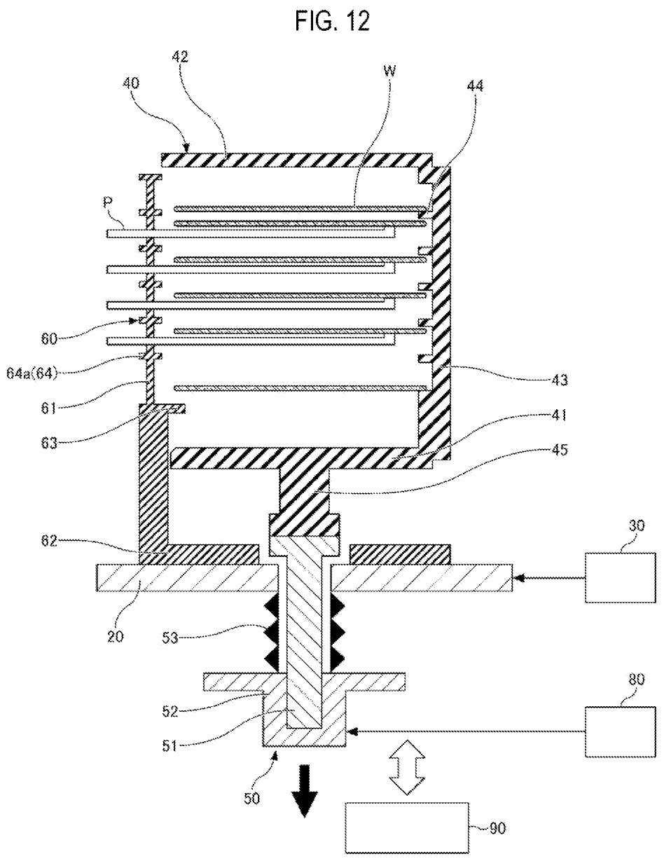

Next, as shown in FIG. 12, the boat driver 80 lowers the boat 40 by the pitch Z1. As a result, the substrates W held by the boat 40 are transferred to the picks P.

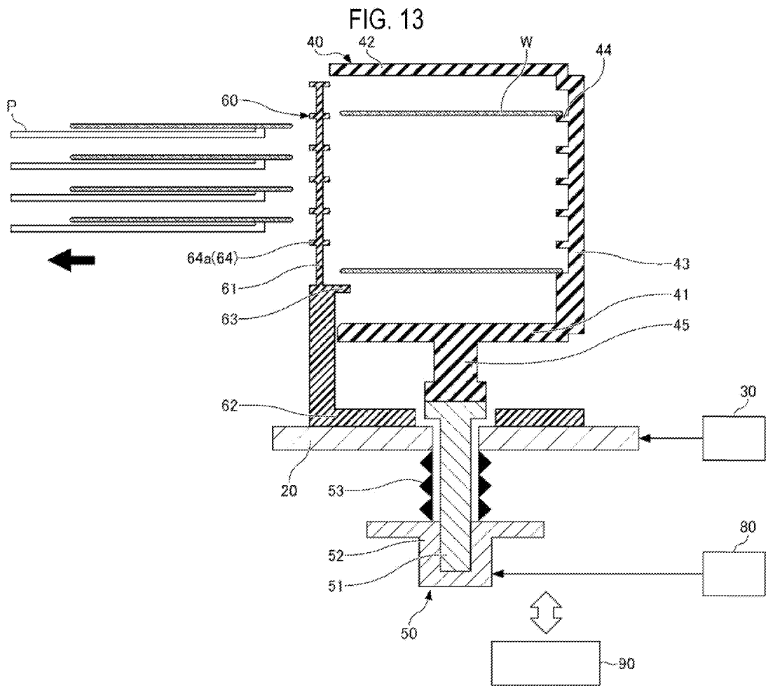

Next, as shown in FIG. 13, the transfer device horizontally moves the picks P holding the substrates W, thereby unloading the picks P from the inside of the boat 40. In this case, since the height of the upper surface of each ring body 64 is approximately the same as the height of the upper surface of each corresponding substrate W, each ring body 64 does not interfere with unloading of the picks P.

Through the above operations, four substrates W are unloaded from the boat 40. By repeating the operations shown in FIGS. 10 to 13, the other substrates W held by the boat 40 may be unloaded. The number of substrates W unloaded from the boat 40 at one time is not limited to four.

According to the second embodiment described above, it is possible to change the relative position between the boat 40 and the ring 60 in a vertical direction. In this case, when the substrates W held by the boat 40 are unloaded by the picks P, the substrates W are transferred from the boat 40 to the picks P by inserting each pick P between the vertically adjacent substrates W and then lowering the boat 40 with respect to the pick P and the ring 60. Therefore, the substrates W may be held by the boat 40 at the same pitch as in the case without the ring 60. That is, the substrates W may be held at a narrow pitch.

### Third Embodiment

### (Substrate Processing Apparatus)

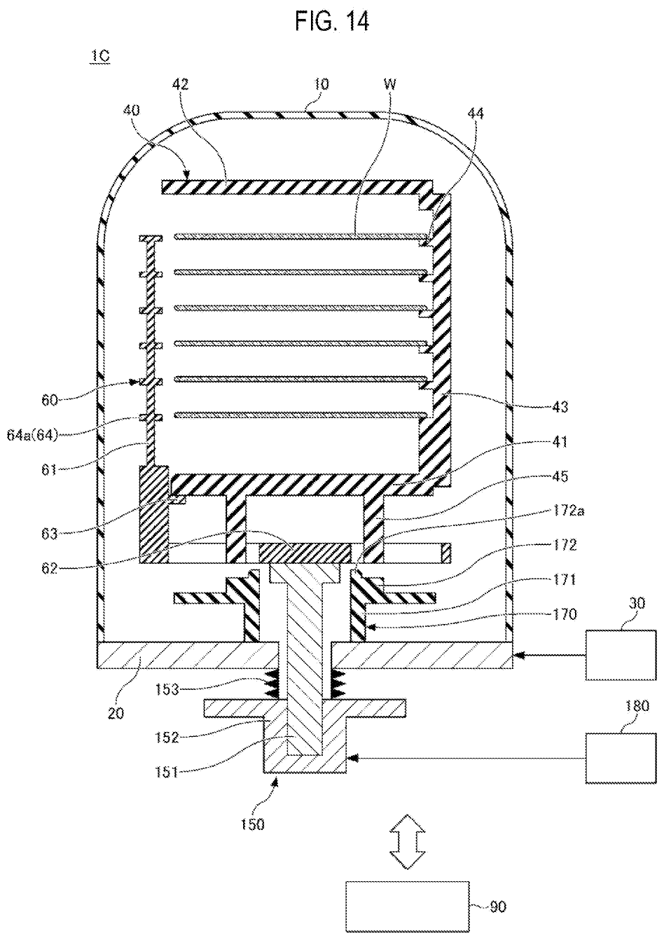

A substrate processing apparatus 1C according to a third embodiment will now be described with reference to FIG. 14. FIG. 14 is a cross-sectional view showing the substrate processing apparatus 1C according to the third embodiment.

The substrate processing apparatus 1C differs from the substrate processing apparatus 1A in that the ring 60 is configured to be capable of being raised and lowered with respect to the lid 20. The other configurations of the substrate processing apparatus 1C may be the same as the configurations of the substrate processing apparatus 1A. Hereinafter, a description will be given focusing on the configurations different from the substrate processing apparatus 1A.

The substrate processing apparatus 1C includes the reaction tube 10, the lid 20, the lid driver 30, the boat 40, a ring support 150, the ring 60, a boat stage 170, a ring driver 180, and the controller 90.

The ring support 150 includes a rotating shaft 151, a bearing 152, and a bellows 153. The rotating shaft 151 is connected to a lower end of the bottom plate 62. The rotating shaft 151 extends below the lid 20 by passing through the lid 20. The bearing 152 is attached to a lower portion of the rotating shaft 151. The bearing 152 rotatably supports the rotating shaft 151 around a vertical axis. The bellows 153 is provided between the lid 20 and the bearing 152 so as to surround an outer periphery of the rotating shaft 151. Thereby, the reaction tube 10 is kept airtight.

The boat stage 170 is made of quartz, for example. The boat stage 170 includes a cylindrical portion 171 and a flange portion 172. The cylindrical portion 171 is fixed on the lid 20. The cylindrical portion 171 surrounds the rotating shaft 151. The flange portion 172 is provided at an upper portion of the cylindrical portion 171 so as to protrude outward in a radial direction of the cylindrical portion 171. A cylindrical leg 45 is placed on the flange portion 172. Thereby, the boat 40 is held by the boat stage 170. An upper surface of the flange portion 172 is provided with, for example, a cylindrical convex portion 172a inserted through an inside of the cylindrical leg 45. When the leg 45 is placed on the flange portion 172, the convex portion 172a is inserted through the inside of the leg 45, so that a position of the boat 40 is determined in a horizontal direction with respect to the boat stage 170.

The ring driver 180 changes the relative position between the boat 40 and the ring 60 in a vertical direction by raising and lowering the ring 60. The ring driver 180 raises and lowers the bearing 152. As a result, the ring 60 and the rotating shaft 151 are raised and lowered together with the bearing 152. The ring driver 180 is a linear motion mechanism including, for example, a ball screw and a servo-motor.

### (Substrate Transfer Method)

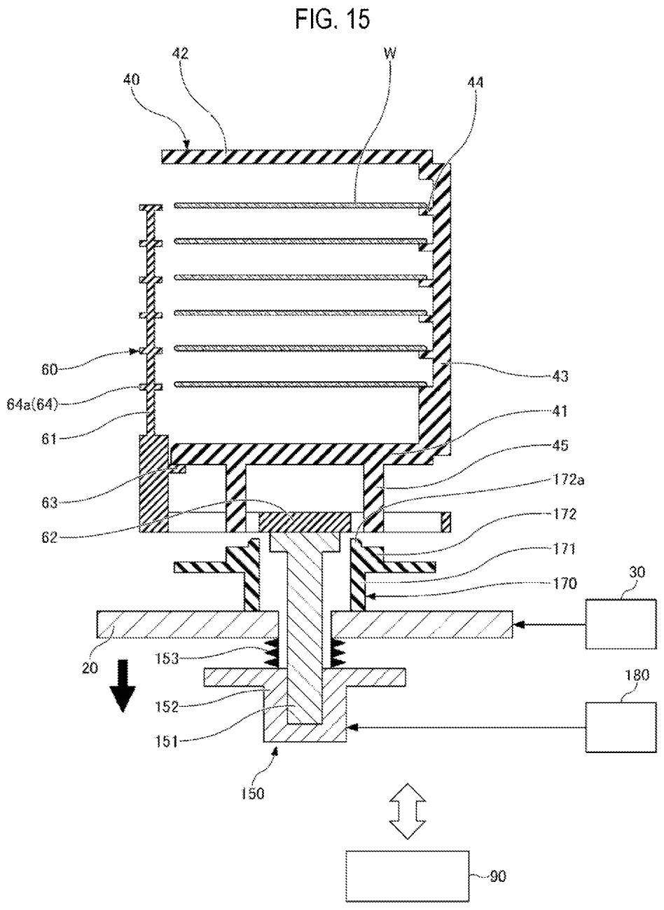

An example of a substrate transfer method according to the third embodiment will now be described with reference to FIGS. 15 to 19. Hereinafter, a method of unloading the substrates W held by the boat 40 will be described. The substrates W may be loaded into the boat 40 by a reverse procedure of the unloading method.

FIGS. 15 to 19 are cross-sectional views illustrating the substrate transfer method according to the third embodiment. The substrate transfer method described below is executed by the controller 90 controlling the operation of each portion of the substrate processing apparatus 1C. The substrate transfer method described below is executed, for example, after processing is performed on a plurality of substrates W held by the boat 40 inside the reaction tube 10.

First, as shown in FIG. 15, the lid driver 30 lowers the lid 20 to unload the boat 40 and the ring 60 from the inside of the reaction tube 10. In this case, the bottom plate 41 is placed on the intermediate plate 63, and the height of the upper surface of each ring body 64 is approximately the same as the height of the upper surface of each corresponding substrate W.

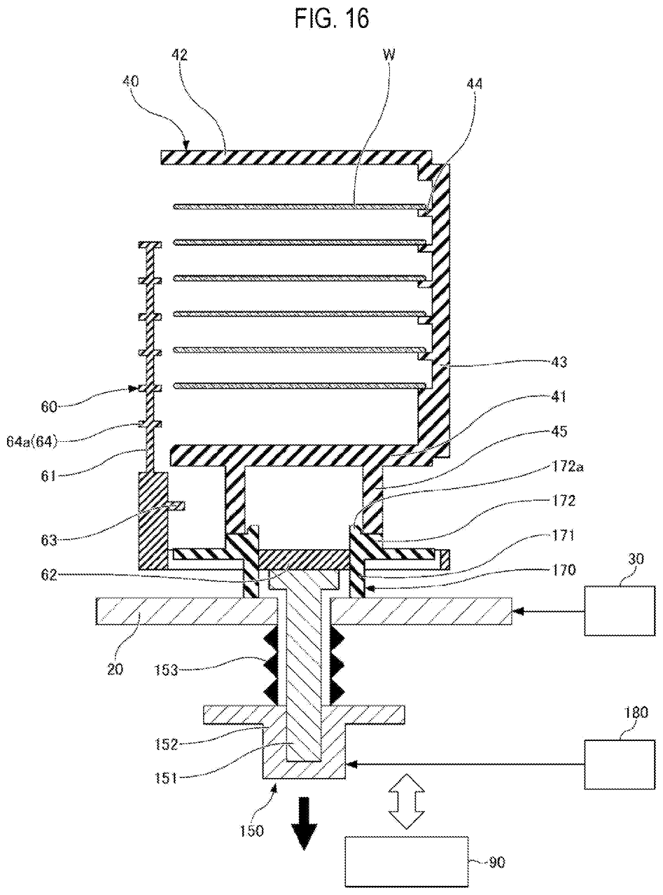

Next, as shown in FIG. 16, the ring driver 180 lowers the ring 60 to place the leg 45 on the flange portion 172.

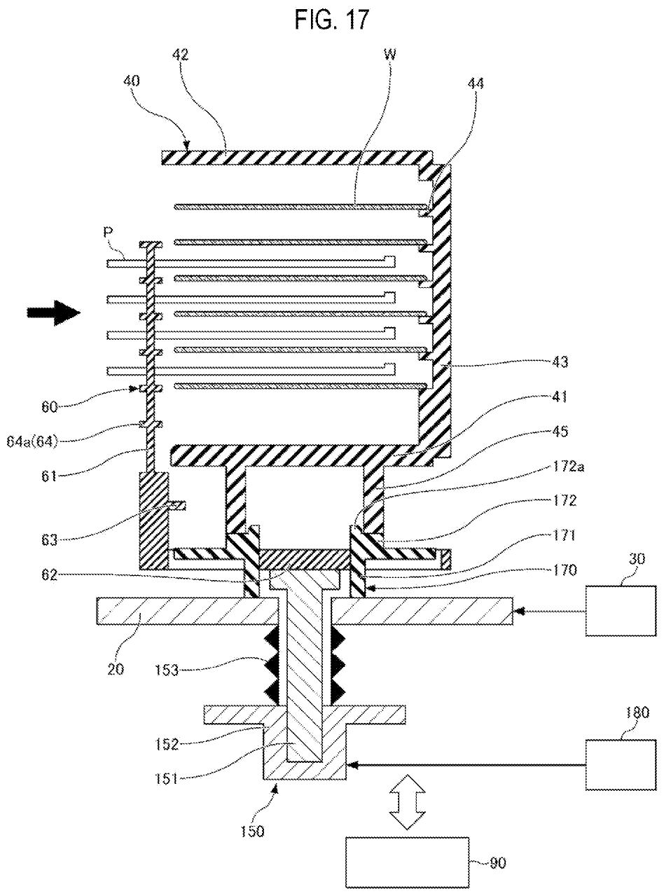

Next, as shown in FIG. 17, a transfer device, which is not shown, horizontally moves the picks P to insert each pick P between the vertically adjacent substrates W. In this case, since the height of the upper surface of each ring body 64 is approximately the same as the height of the upper surface of each corresponding substrate W, each ring body 64 does not interfere with insertion of the picks P.

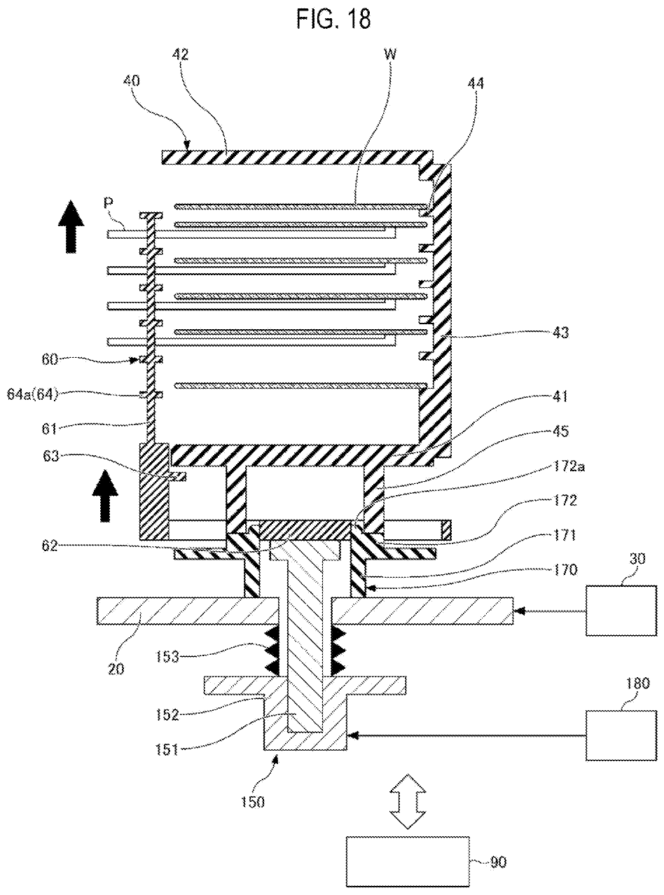

Next, as shown in FIG. 18, the transfer device raises the picks P by the pitch Z1 and the ring driver 180 raises the ring 60 by the pitch Z1. As a result, the substrates W held by the boat 40 are transferred to the picks P.

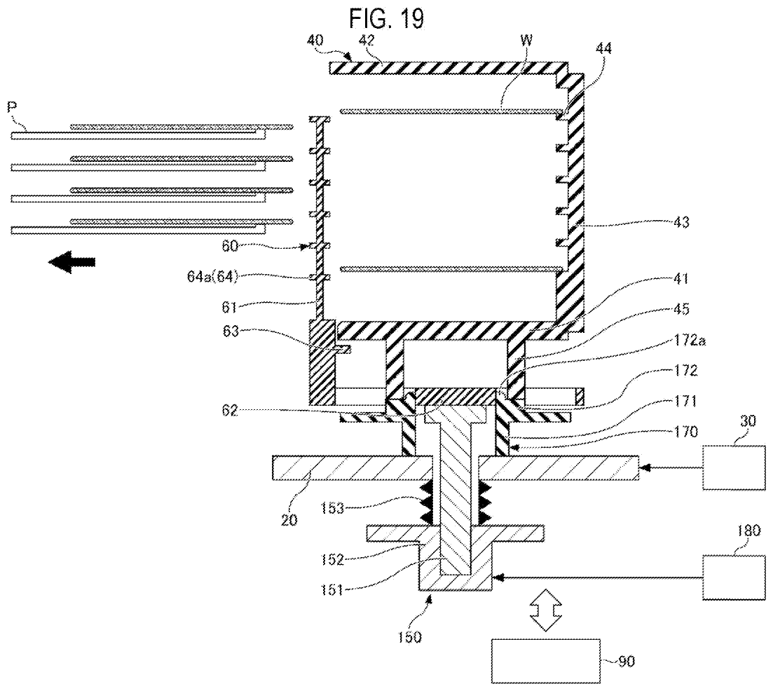

Next, as shown in FIG. 19, the transfer device horizontally moves the picks P holding the substrates W, thereby unloading the picks P from the inside of the boat 40. In this case, since the height of the upper surface of each ring body 64 is approximately the same as the height of the upper surface of each corresponding substrate W, each ring body 64 does not interfere with unloading of the picks P.

Through the above operations, four substrates W are unloaded from the boat 40. By repeating the operations shown in FIGS. 16 to 19, the other substrates W held by the boat 40 may be unloaded. The number of substrates W unloaded from the boat 40 at one time is not limited to four.

According to the third embodiment described above, it is possible to change the relative position between the boat 40 and the ring 60 in a vertical direction. In this case, when the substrates W held by the boat 40 are unloaded by the picks P, the substrates W are transferred from the boat 40 to the picks P by inserting each pick P between the vertically adjacent substrates W and then lowering the boat 40 relative to the pick P and the ring 60. Therefore, the substrates W may be held by the boat 40 at the same pitch as in the case without the ring 60. That is, the substrates W may be held at a narrow pitch.

According to the present disclosure in some embodiments, it is possible to hold substrates at a narrow pitch.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a boat configured to hold substrates by arranging the substrates in a horizontal posture and in multiple stages along a vertical direction;
a plate-shaped member provided along an outer periphery of each substrate of the substrates held by the boat; and
a driver configured to change a relative position between the boat and the plate-shaped member in the vertical direction.

2. The substrate processing apparatus of claim 1, wherein the driver moves the boat relative to the plate-shaped member.

3. The substrate processing apparatus of claim 2, further comprising a position determiner configured to determine a position of the plate-shaped member in a horizontal direction with respect to the boat.

4. The substrate processing apparatus of claim 1, wherein the driver moves the plate-shaped member relative to the boat.

5. The substrate processing apparatus of claim 4, further comprising a position determiner configured to determine a position of the plate-shaped member in a horizontal direction with respect to the boat.

6. The substrate processing apparatus of claim 1, further comprising a position determiner configured to determine a position of the plate-shaped member in a horizontal direction with respect to the boat.

7. A substrate transfer method of unloading substrates from a substrate processing apparatus by a transfer device,
wherein the transfer device includes picks configured to hold the substrates,
wherein the substrate processing apparatus includes a boat configured to hold the substrates by arranging the substrates in a horizontal posture and in multiple stages along a vertical direction, and a plate-shaped member provided along an outer periphery of each substrate of the substrates held by the boat, and
wherein the substrate transfer method comprises:
moving the picks to below the substrates held by the boat; and
transferring the substrates held by the boat to the picks by changing a relative position between the boat and the plate-shaped member in the vertical direction.

8. The substrate transfer method of claim 7, wherein the transferring the substrates to the picks includes lowering the boat relative to the plate-shaped member.

9. The substrate transfer method of claim 7, wherein the transferring the substrates to the picks includes raising the plate-shaped member and the picks relative to the boat.

10. A substrate transfer method of loading substrates into a substrate processing apparatus by a transfer device,
wherein the transfer device includes picks configured to hold the substrates,
wherein the substrate processing apparatus includes a boat configured to hold the substrates by arranging the substrates in a horizontal posture and in multiple stages along a vertical direction, and a plate-shaped member provided along an outer periphery of each substrate of the substrates held by the boat, and
wherein the substrate transfer method comprises:
moving the picks holding the substrates to an inside of the boat; and
transferring the substrates held by the picks to the boat by changing a relative position between the boat and the plate-shaped member in the vertical direction.

11. The substrate transfer method of claim 10, wherein the transferring the substrates to the boat includes raising the boat relative to the plate-shaped member.

12. The substrate transfer method of claim 10, wherein the transferring the substrates to the boat includes lowering the plate-shaped member and the picks relative to the boat.
